(19) United States
(12) Patent Application Publication
(10) Pub. No.: US 2002/0110760 A1
(43) Pub. Date: Aug. 15, 2002

(54) Method for improving hydrophilic character of photoresist and effect of development

(75) Inventor: Francis Lin, Hsin-Chu Tity (TW)

Correspondence Address: Benjamin J. Hauptman, LOWE HAUPTMAN GILMAN & BERNER, Suite 310, 1700 Diagonal Road, Alexandria, VA, 22314, US

(73) Assignee: Macronix International Co., Ltd.

(21) Appl. No.: 09/779,474

(22) Filed: Feb. 9, 2001

(51) Int. Cl. G03F 7/00; G03F 7/38

(52) U.S. Cl. 430/322; 430/327; 430/330

(57) ABSTRACT

A method for improving hydrophilic character of photoresist, comprises following steps: provide a substrate which is placed inside a chamber; form a photoresist on the substrate; transmit a gas into the chamber, where the gas contains the water vapor; perform a thermal treatment process in which the photoresist being covered by the gas; and perform a pattern transfer process such that a pattern on a mask is transferred into the photoresist which has been treated by the thermal treatment process. And a method for improving effect of development, comprises: provide a substrate which is placed inside a chamber; form a photoresist on the substrate; transmit a first gas into the chamber, where the first gas containing the water vapor; perform a soft bake process in which the photoresist is covered by the first gas; perform a first cooling process such that both the photoresist and the substrate are cooled; perform an expose process such that a pattern on a mask is transferred into the photoresist; transit second gas which also containing the water vapor into the chamber; perform a post expose bake process where the photoresist is covered by the second gas during the post expose bake process; perform a second cooling process to let both the photoresist and the substrate are cooled; and perform a development process in which a developer is used to develop the pattern in the photoresist.

### BACKGROUND OF THE INVENTION

1. Field of the Invention

The invention pertains to a method for improving effect of development, and particularly relates to a method which enhances adhesion between developer and surface of photoresist by improving hydrophilic character of photoresist.

2. Description of the Prior Art

In the photolithography fabrication which transfers pattern on mask into photoresist, the step of development is used to develop the pattern in the photoresist which has been baked and exposed. Whereby, developer is used to partial of photoresist which does not correspond to any pattern, and then only partial photoresist which corresponds to the pattern is reserved.

In general, after pattern on mask has been transferred into photoresist which located on surface layer 11, which locates on substrate 10, photoresist is divided into two parts: pattern photoresist 121 which corresponds to pattern, and non-pattern photoresist 122 which corresponds to nothing, as shown in FIG. 1A. In the Next step, developer 13 is distributed, by the spray/puddle way or other ways, on photoresist to let every part of photoresist is covered by developer 13, as FIG. 1B shows. Then, uses positive photoresist as example, pattern photoresist 122 is removed by developer 13 and then only non-pattern photoresist 121 is reserved, as FIG. 1C shows, Thus, reserved non-pattern photoresist 121 could be used to define required pattern in underlying surface layer 11 in following processes such as etch, as FIG. 1D show. Certainly, although shown example is positive photoresist, same action is appeared for negative photoresist.

However, because most of current photoresists, both positive photoresist and negative photoresist, are made of organic materials, hydrophilic character of current photoresists are too bad to let developer 13 fully adhere on surface of photoresist. Especially, thermal treatment processes, such as bake and cool, which are performed before development trends to let photoresist, especially surface of photoresist, lose water. Therefore, a direct result is that ideal cases shown in FIG. 1B maybe be replaced by these cases shown in both FIG. 2A and FIG. 2B: micro-bubbles 14 appear on part surface of pattern photoresist 122, or amount of developer 14 on pattern is not uniform which induces partial pattern photoresist 122 could not be removed for developer 13 is insufficient. Then, the ideal case shown in FIG. 2C maybe be replaced by these cases shown in both FIG. 2C and FIG. 2D: partial of pattern photoresist 122 is thoroughly removed, but partial of pattern photoresist 122 is not thoroughly removed and is reversed. Naturally, while reversed pattern photoresist 122 corresponds to line or space, damages such as line width variation or bridge will be happened; while reversed pattern photoresist 122 corresponds to contact hole, damages such as hole width variation or blind contact will be happened.

Aims at previous disadvantages, often-seen solution of well-known technology at least includes precisely control temperature and humidity of reaction temperature, uses developer with rich interface active agent or uses developer with higher hydrophilic character, but each available solution can not avoid following disadvantages such as complicated fabrication and high production cost. Moreover, each bake process which performed before development process always dry photoresist and then hydrophilic character of photoresist is further degraded. Indisputably, defects shown in FIG. 2A through FIG. 2B can not be totally avoid, and these defects are more serious while critical dimension of pattern is continually decreased and required precision of development is further increased.

In summary, well-known technology can not effectively solve improper development which induced by bad hydrophilic character of photoresist with low cost. Then, it is desired to develop new technology for overcoming this problem, especially to develop a simple and cheap method which can be applied in practical production line.

### SUMMARY OF THE INVENTION

Objects of the present invention at least include providing a method for improving improper development induced by bad hydrophilic character of photoresist.

Objects of the present invention further comprise providing a simple and cheap method to improve effect of development on the practical production line.

On the whole, one method present by the invention is a method for improving hydrophilic character of photoresist, which at least includes: provide a substrate which is placed inside a chamber; form a photoresist on the substrate; transmit a gas into the chamber, where the gas contains the water vapor; perform a thermal treatment process in which the photoresist being covered by the gas; and perform a pattern transfer process such that a pattern on a mask is transferred into the photoresist which has been treated by the thermal treatment process.

Another method present by the invention is a method for improving effect of development, which at least comprises: provide a substrate which is placed inside a chamber; form a photoresist on the substrate; transmit a first gas into the chamber, where the first gas containing the water vapor; perform a soft bake process in which the photoresist is covered by the first gas; perform a first cooling process such that both the photoresist and the substrate are cooled; perform an expose process such that a pattern on a mask is transferred into the photoresist; replace the first gas by a second gas which also containing the water vapor; perform a post expose bake process where the photoresist is covered by the second gas during the post expose bake process; perform a second cooling process to let both the photoresist and the substrate are cooled; and perform a development process in which a developer is used to develop the pattern in the photoresist.

### BRIEF DESCRIPTION OF THE DRAWINGS

Preferred embodiments of the invention are described below with reference to the following accompanying drawings.

FIG. 1A through FIG. 1D are some brief cross-section illustrations about ideal conditions of several steps for using developer to develop pattern;

FIG. 2A through FIG. 2D are some brief cross-section illustrations about real conditions of several steps for using developer to develop pattern;

FIG. 3 is a brief flow chart of one preferred embodiments of this invention; and

FIG. 4 is a brief flow chart of another preferred embodiments of this invention.

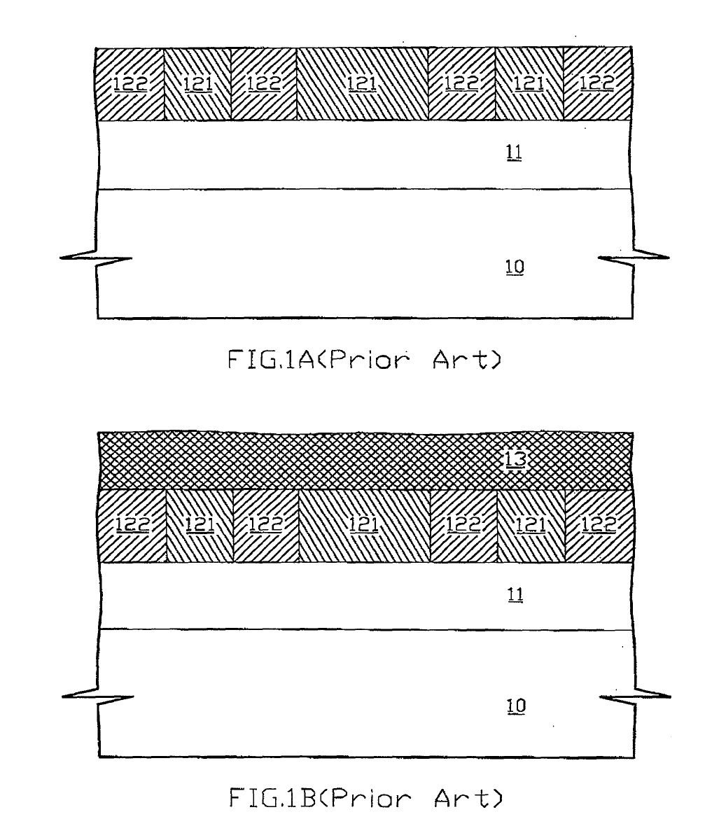

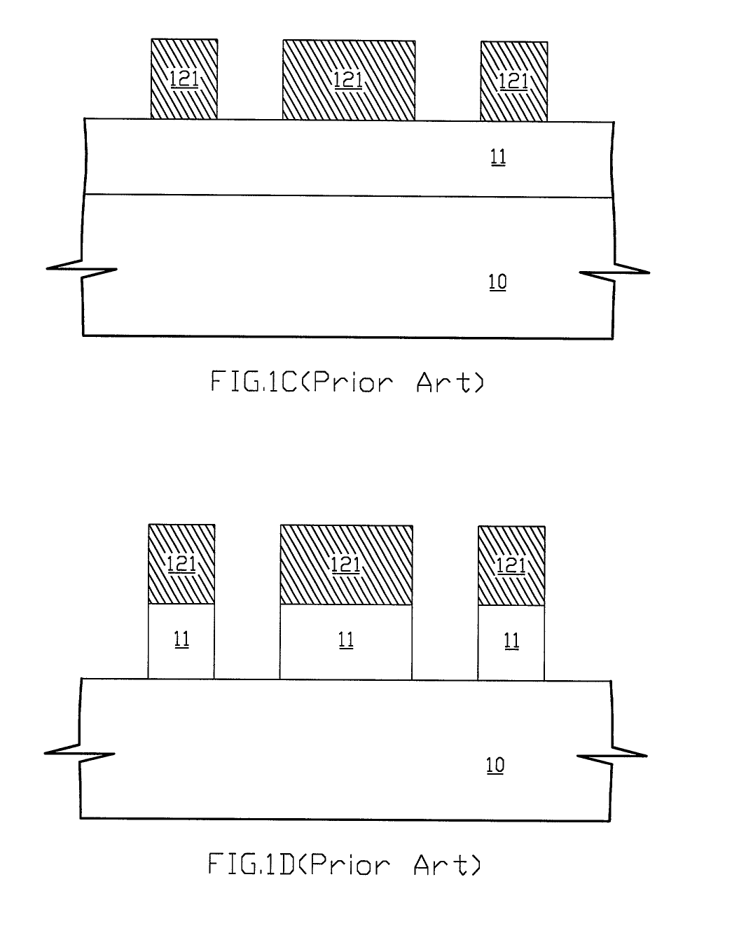

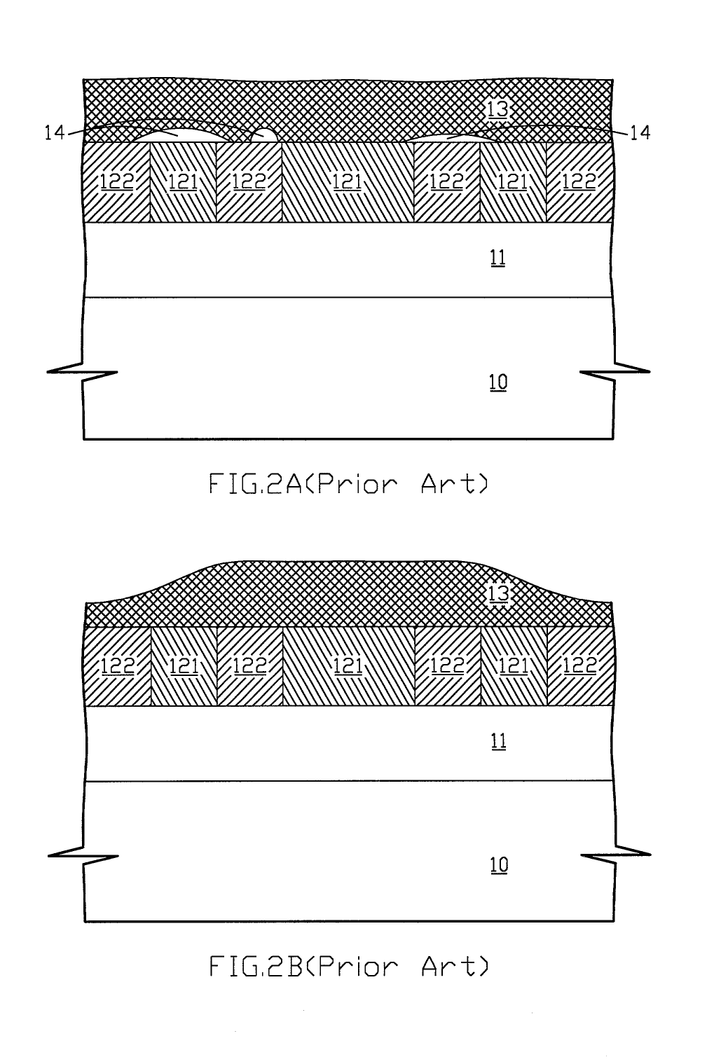

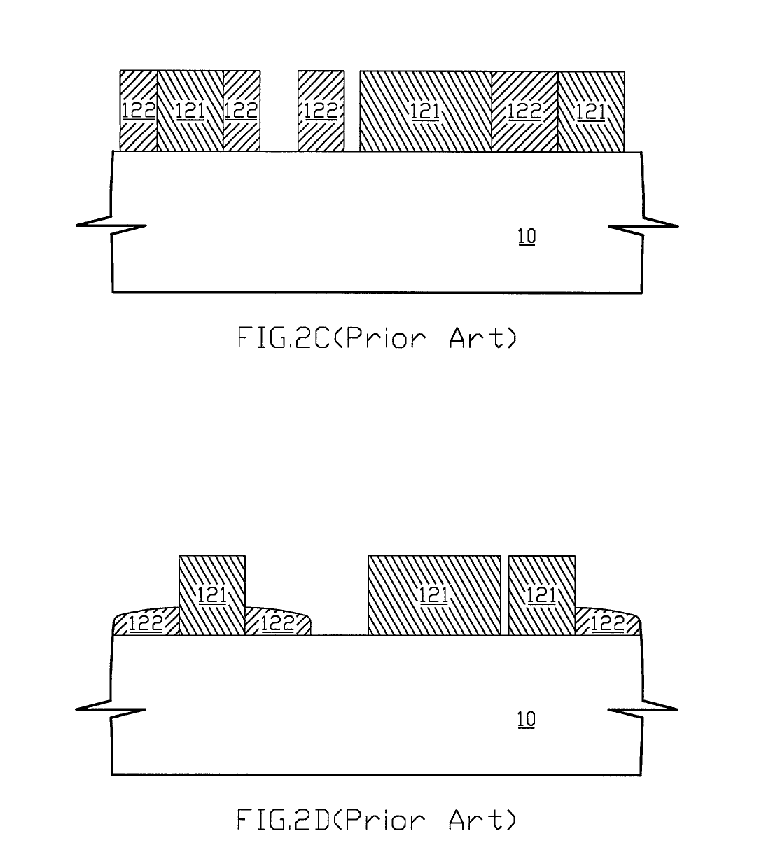

### DESCRIPTION OF THE PREFERRED EMBODIMENT

Aims at disadvantages induced by the fact that developer can not well adheres on photoresist for bad hydrophilic character of photoresist, well-known technology usually solute these disadvantages by precisely controlling temperature and humidity of reaction temperature, using developer with rich interface active agent or using developer with higher hydrophilic character. By these well-known technology, disadvantages such as complicated fabrication and high production cost are unavoidable, and a more serious defect it that each bake process which performed before development process always dry photoresist and then hydrophilic character of photoresist is further degraded. In contrast, Applicant of the claimed invention present a new entrance way to solve induced by bad hydrophilic character of photoresist: no specific photoresist, no specific developer on no specific environment is used to improve adhesion between developer and photoresist, and then photoresist is continually dried in thermal treatment process, but a gas, which contain water vapor, is continually applied to completely cover surface of photoresist, such that surface of photoresist always has enough water to let developer can fully adhere on surface of photoresist. In other words, essential idea of the claimed invention is continually externally provide water to surface of photoresist before it is developed for improving hydrophilic character of photoresist. The claimed invention never uses skills used by well-known solution such as uses new material to form developer (or photoresist) or uses a precise fabrication or a precise environment.

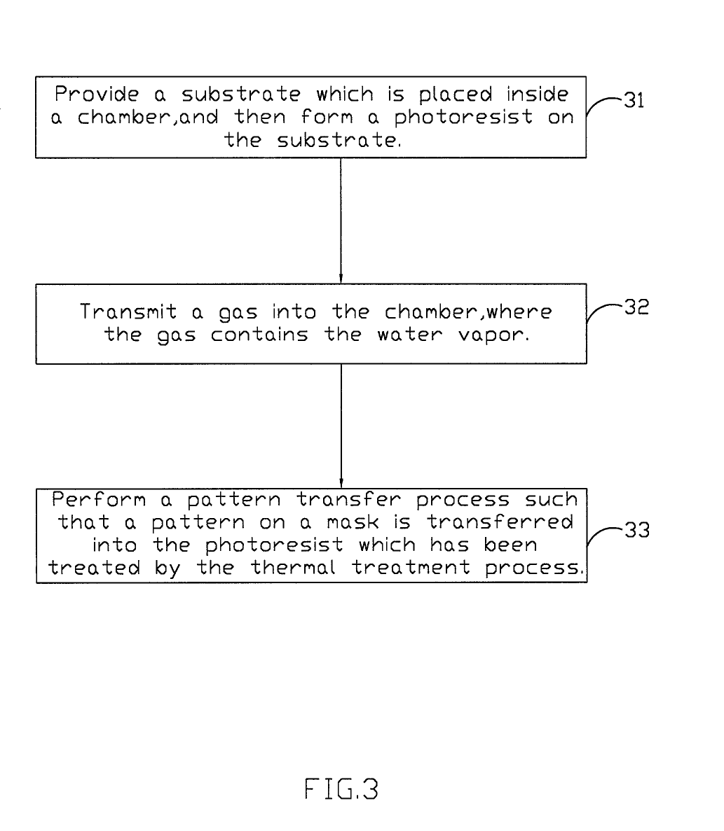

One preferred of this invention is a method for improving hydrophilic character of photoresist, especially is a method which enhances precision of pattern transfer by improving hydrophilic character of photoresist. As shown in FIG. 3, the method at least includes following essential steps:

As photoresist block 31 shows, provide a substrate which is placed inside a chamber, and then form a photoresist on the substrate. This chamber usually comprises a holder for holding substrate. Futher, while both thermal treatment process and pattern transfer process are performed in the chamber, the chamber further comprises a pattern transfer equipment for transferring pattern of mask into photoresist. Moreover, photoresist usually is a combination of resin, sensitizer and solvent, and materials of photoresist usually are organic materials. Whereby, photoresist could be liquid photoresist solution or partial cured photoresist solution.

As water vapor environment thermal treatment block 32 shows, transmit a gas into the chamber, where the gas contains the water vapor; and then perform a thermal treatment process in a condition that photoresist being covered by the gas. In general, available gas is nitrogen or inert gas. Moreover, as usual, partial solvent of said photoresist is removed during said thermal treatment process.

As pattern transfer block 33 shows, perform a pattern transfer process such that a pattern on a mask is transferred into the photoresist which has been treated by the thermal treatment process. Certainly, an optional step is further performing a cooling process after this thermal treatment process and before so-called pattern transfer process. Further, in the cooling process this photoresist also is completely covered by the gas with water vapor.

Significantly, in the step of water vapor environment thermal treatment block 32, the gas, which contains water vapor, can provide water to surface of photoresist such that hydrophilic character of photoresist is improved. On the other hand, it could be considered as that water particles are formed on surface of photoresist, and then it is easier for developer to fully adhere on surface of photoresist. Beside, because heat capacity of water is larger than both gas and most of organic materials, this method can let temperature distribution is more uniform over all surface of photoresist by application of water vapor, and a direct advantage of this method is that damages induced by non-uniform temperature, such as CD (critical dimension) nonuniformality, can be properly prevented. Accordingly, application of this method can avoid application precisely controlled reaction environment, application of developer with rich interface active agent, and application of developer with high Hydrophilic Character, and then a direct advantage is that cost of this method is less than conventional technology.

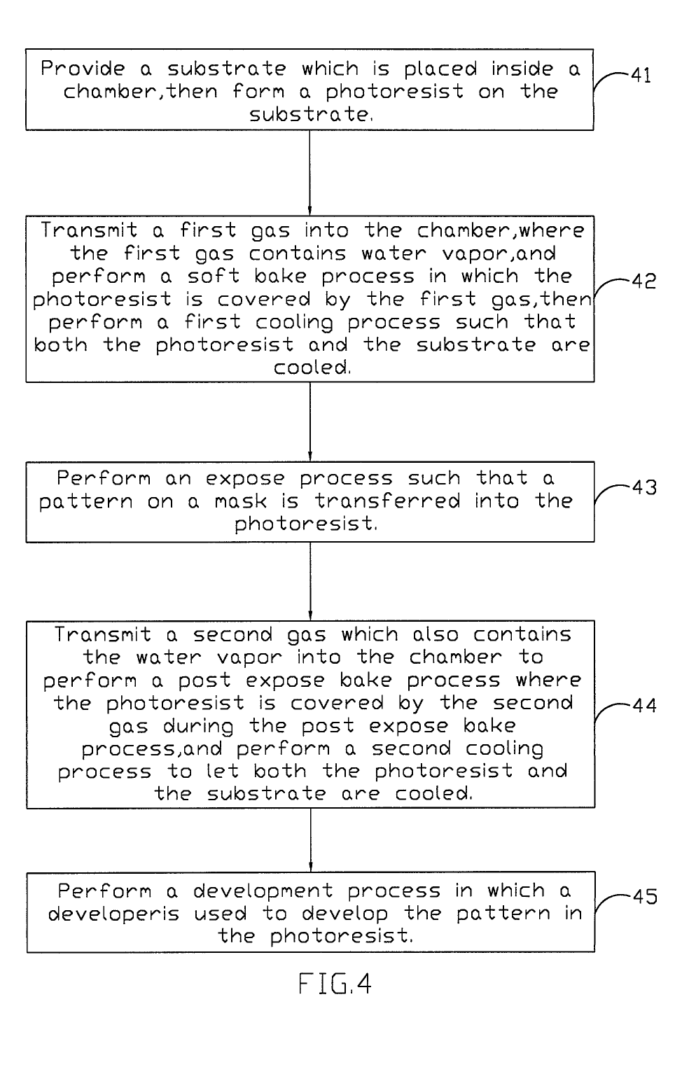

Another embodiment of this invention is a method for improving effect of development, especially is a method for preventing degradation of adhesion between developer and photoresist which induced by back process performed before photoresist is developed. As shown in FIG. 4, this method at least includes following essential steps:

As photoresist cover block 41 shows, provide a substrate which is placed inside a chamber, then form a photoresist on the substrate. Futher, while both thermal treatment process and pattern transfer process are performed in the chamber, the chamber comprises a pattern transfer equipment for transferring pattern of mask into photoresist. Moreover, photoresist usually is a combination of resin, sensitizer and solvent, and materials of photoresist usually are organic materials. Whereby, photoresist could be liquid photoresist solution or partial cured photoresist solution.

As soft back block 42 shows, transmit a first gas into the chamber, where the first gas contain water vapor, and then perform a soft bake process in which the photoresist is covered by the first gas, then perform a first cooling process such that both the photoresist and the substrate are cooled. Herein, first gas usually is nitrogen or inert gas, and both photoresist and substrate usually are covered by the first gas with contained water vapor.

As expose block 43 shows, perform an expose process such that a pattern on a mask is transferred into the photoresist.

As post expose back block 44 shows, transmit a second gas which also containing the water vapor into the chamber, and perform a post expose bake process where the photoresist is covered by the second gas during the post expose bake process, and then perform a second cooling process to let both the photoresist and the substrate are cooled. Herein, second gas usually is nitrogen or inert gas, and both photoresist and substrate usually are covered by the second gas with contained water vapor

As development block 45 shows, perform a development process in which a developer is used to develop the pattern in the photoresist. Whereby, developer in distributed over photoresist during said development process by a spray/puddle way. Further, this method comprise performing an after develop inspection after this development process is finished for ensuring the accuracy of development process.

Significantly, because photoresist is covered by gas, which contain water vapor, in each bake process, although photoresist will lose water during each bake process, lost water can be compensated by gas with water vapor and then hydrophilic character of photoresist would not be degraded by any bake process which is performed before development process. Besides, because water is transmitted by gas (carrier gas) and technology for transmitting gas into chamber is well-known, only gas pipeline(s), value(s), water source(s) and gas source(s) are necessary, at most a heater is required to form water vapor and adjust temperature of water vapor, this method is a low cost method and can be practically applied in production line.

Although specific embodiments have been illustrated and described, it will be obvious to those skilled in the art that various modifications may be made without departing from what is intended to be limited solely by the appended claims.

What is claimed is:

1. A method for improving hydrophilic character of photoresist, comprising:
providing a substrate, wherein said substrate is placed inside a chamber;
forming a photoresist on said substrate;
transmitting a gas into said chamber, said gas containing the water vapor;
performing a thermal treatment process, said photoresist being covered by said gas during said thermal treatment process; and
performing a pattern transfer process, wherein a pattern on a mask is transferred into said photoresist which has been treated by said thermal treatment process.

2. The method of claim 1, wherein said chamber comprises a holder for holding said substrate.

3. The method of claim 1, wherein said photoresist is made of a plurality of organic materials.

4. The method of claim 1, wherein said photoresist is a photoresist solution.

5. The method of claim 1, wherein said photoresist is a partially cured photoresist solution.

6. The method of claim 1, wherein said gas is nitrogen.

7. The method of claim 1, wherein said gas is inert gas.

8. The method of claim 1, wherein partial solvent of said photoresist is removed during said thermal treatment process.

9. The method of claim 1, wherein said chamber further comprises a pattern transfer equipment for transferring said pattern of said mask into said photoresist.

10. The method of claim 1, further comprise performing a cooling process after said thermal treatment process and before said pattern transfer process, said photoresist being completely covered by said gas.

11. A method for improving effect of development, comprising:
providing a substrate, wherein said substrate is placed inside a chamber;
forming a photoresist on said substrate;
transmitting a first gas into said chamber, said first gas containing a water vapor;
performing a soft bake process, said photoresist being covered by said first gas during said soft bake process;
performing a first cooling process, such that both said photoresist and said substrate are cooled;
performing an expose process, wherein a pattern on a mask is transferred into said photoresist;
transmitting a second gas into said chamber, wherein said second gas also containing a water vapor;
performing a post expose bake process, said photoresist being covered by said second gas during said post expose bake process;
performing a second cooling process, such that both said photoresist and said substrate are cooled; and
performing a development process, wherein a developer is used to develop the pattern in said photoresist.

12. The method of claim 11, wherein said chamber further comprises a pattern transfer equipment for transferring said pattern of said mask into said photoresist.

13. The method of claim 11, wherein said photoresist is made of a plurality of organic materials.

14. The method of claim 11, wherein said photoresist is chosen from the group consisting of the photoresist solution and the partial cured photoresist solution.

15. The method of claim 11, wherein said first gas is chosen from the group consisting of nitrogen and inert gas.

16. The method of claim 11, wherein said second gas. is chosen form the group consisting of nitrogen and inert gas.

17. The method of claim 11, wherein said developer is distributed over said photoresist during said development process by a spray/puddle way.

18. The method of claim 11, further comprise performing an after develop inspection after said development process is finished for ensuring the accuracy of said development process.

19. The method of claim 11, wherein said photoresist is completely covered by said first gas during said first cooling process.

20. The method of claim 11, wherein said photoresist is completely covered by said second gas during said second cooling process.
